(19) United States
(12) Patent Application Publication
(10) Pub. No.: US 2025/0118593 A1
(43) Pub. Date: Apr. 10, 2025

(54) PROCESSING CHAMBER WITH RF RETURN PATH

(71) Applicant: Applied Materials, Inc., Santa Clara, CA (US)

(72) Inventors: Vellaichamy NAGAPPAN, Bangalore (IN); Viren KALSEKAR, Sunnyvale, CA (US); Vinay K. PRABHAKAR, Cupertino, CA (US); Siva CHANDRASEKAR, Bengaluru (IN); Satish RADHAKRISHNAN, San Jose, CA (US); Tuan Anh (Mike) NGUYEN, San Jose, CA (US); Saket RATHI, Santa Clara, CA (US)

(21) Appl. No.: 18/904,967

(22) Filed: Oct. 2, 2024

(30) Foreign Application Priority Data
Oct. 6, 2023 (IN) 202341067037

(51) Int. Cl. H01L 21/687; C23C 16/455; C23C 16/458; C23C 16/505

(52) U.S. Cl. CPC H01L 21/68785; C23C 16/45536; C23C 16/45544; C23C 16/4583; C23C 16/505

(57) ABSTRACT

Embodiments of the present disclosure relate to a processing chamber. The process chamber includes a lid assembly, a choke plate, a pedestal assembly, a ground plate, and a ground ring. A processing region is defined between the lid assembly and the pedestal assembly. The pedestal assembly includes an isolator plate assembly. The isolator plate assembly includes three or more plates. Each plate includes one or more alignment tabs, one or more protrusions, one or more lift pin holes, a ground plate, and a ground ring. The lid assembly, choke plate, and pedestal assembly form a RF return path. The ground plate, includes a cylindrical core, an annular body, and an annular projection. The ground ring includes an annular body, an annular wall, an annular connector, and an annular tab. The ground ring and the ground plate are electrically connected via a RF strap.

### CROSS-REFERENCE TO RELATED APPLICATIONS

This application claims benefit of Indian provisional patent application Ser. No. 20/234,1067037, filed Oct. 6, 2023, which is herein incorporated by reference.

### BACKGROUND

### Field

Embodiments disclosed herein generally relate to a processing chamber for depositing one or more layers on a substrate. In particular, the embodiments disclosed herein relate to a processing chamber with an RF return path.

### Description of the Related Art

Integrated circuits may include more than one billion field effect transistors (e.g., complementary metal-oxide-semiconductor (CMOS) field effect transistors) that are formed on a substrate (e.g., semiconductor wafer) and which cooperate to perform various functions within the circuit. Reliably producing smaller features is one of the key technologies for the next generation of very large scale integration (VLSI) and ultra-large-scale integration (ULSI) of semiconductor devices, particularly for the 3 nanometer (N3) node. However, as the limits of integrated circuit technology are pushed, the shrinking dimensions of interconnects in VLSI and ULSI technology have placed additional demands on processing capabilities. Reliable formation of the gate pattern is important to integrated circuits success and to the continued effort to increase circuit density and quality of individual substrates and die.

Contamination of semiconductor devices may occur due to metal contamination caused by damage and corrosion to the processing chamber. For example, high temperatures and the use of volatile gases in a processing chamber may cause damage and corrosion to the processing chamber. The damage and corrosion may then affect processes that are performed within the chamber and may also require replacement of various components within the processing chamber and/or replacement of the processing chamber itself.

Therefore, there is a need in the art for improved techniques for reducing damage and corrosion within a processing chamber.

### SUMMARY

Embodiments disclosed herein generally relate to a processing chamber for depositing one or more layers on a substrate. In particular, the embodiments disclosed herein relate to a processing chamber with an RF return path.

In one embodiment, a process chamber is disclosed. The process chamber includes a lid assembly, a choke plate, a pedestal assembly, a ground plate, and a ground ring. A processing region is defined between the lid assembly and the pedestal assembly. The pedestal assembly includes an isolator plate assembly. The isolator plate assembly includes three or more plates. Each plate includes one or more alignment tabs, one or more protrusions, one or more lift pin holes, a ground plate, and a ground ring. The lid assembly, choke plate, and pedestal assembly form a RF return path.

In another embodiment, a processing system suitable for semiconductor substrate processing is disclosed. The processing system includes a lid assembly, a choke plate, a pedestal assembly, an isolator plate assembly, a ground plate, and a ground ring. A processing region is defined between the lid assembly and the pedestal assembly. The ground plate includes a cylindrical core, an annular body, and an annular projection. The lid assembly, the choke plate, and the pedestal assembly form a RF return path.

In yet another embodiment, a control unit of a process system is disclosed. The process system stores instructions that, when executed by a processor, cause the system to process a substrate within a processing chamber by receiving a substrate on a heater pedestal of a pedestal assembly. The pedestal assembly moves from a cleaning position to a processing position. A RF power is applied to the processing chamber along a RF return path to create a bias between a showerhead and the pedestal assembly. The substrate is processed and the pedestal assembly is moved from the processing position to the cleaning position. The substrate is removed from the processing chamber and the processing chamber is cleaned. The processing chamber includes a lid assembly, a choke plate, the pedestal assembly, and an isolator plate assembly. The lid assembly includes a showerhead having one or more holes. A processing region is defined between the lid assembly and the pedestal assembly. The pedestal assembly includes a ground plate, and a ground ring. The ground ring includes an annular body, an annular wall, an annular connector, and an annular tab. The ground ring and the ground plate are electrically connected via a RF strap. The lid assembly, the choke plate, and the pedestal assembly form a RF return path.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic side view of a processing chamber having a pedestal assembly in a deposition position, according to embodiments.

FIG. 1B is a schematic side view of the processing chamber of FIG. 1A having a pedestal assembly in a cleaning position, according to embodiments.

FIG. 2A is a cross-sectional view of the isolator plate assembly, the ground plate, and the ground ring included in the processing chamber of FIG. 1A, according to embodiments.

FIG. 2B is a top view of a plate of the isolator plate assembly, according to embodiments.

FIG. 2C is a cross-sectional perspective view of the ground plate and the ground ring, according to embodiments.

FIG. 2D is a top view of the ground ring, according to embodiments.

FIG. 2E is a cross-sectional view of the annular tab, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to a processing chamber for depositing one or more layers on a substrate. In particular, the embodiments disclosed herein relate to a processing chamber with an RF return path. Various embodiments described herein allow for a reduction in the corrosion and/or other types of damage that may occur when processing a substrate within a processing chamber. Additionally, various embodiments enable the costs of components included in a processing chamber to be reduced, for example, by reducing manufacturing and material costs.

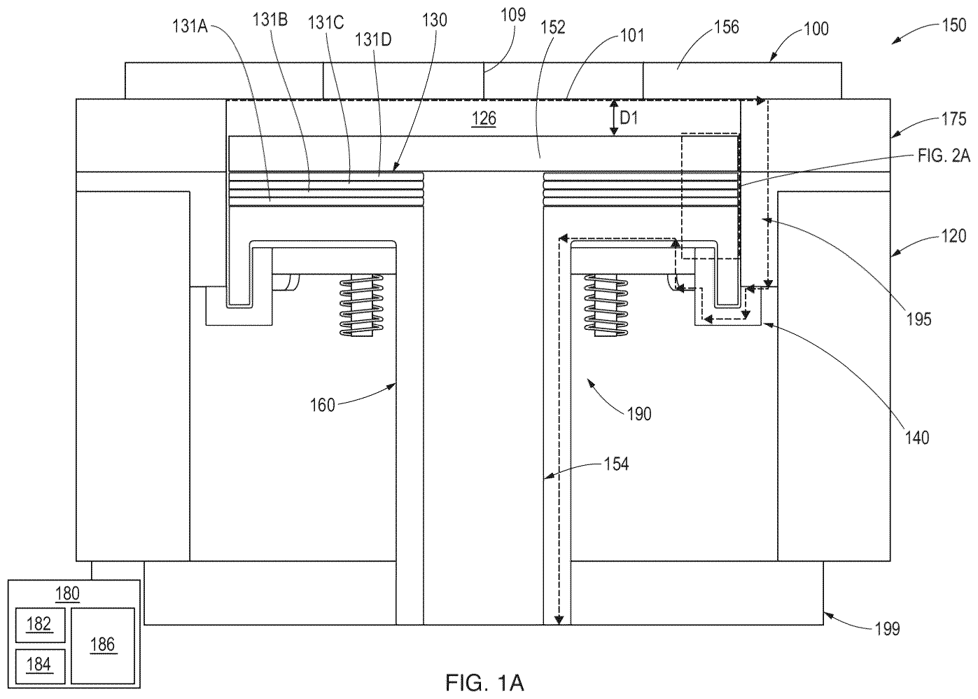

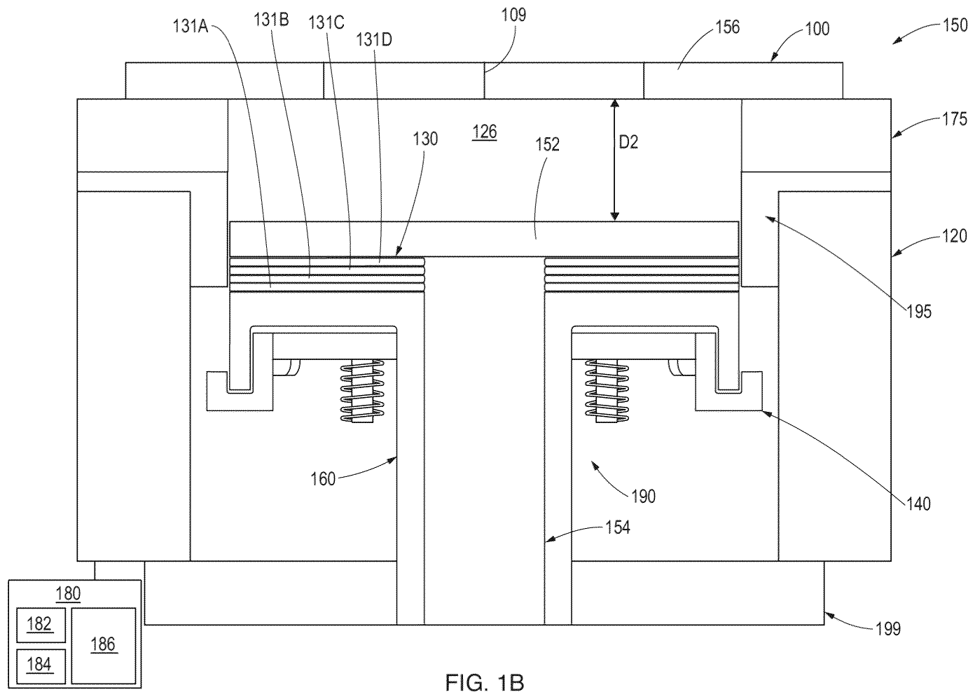

FIG. 1A is a schematic side view of a processing chamber 150 having a pedestal assembly 190 in a deposition position. FIG. 1B is a schematic side view of a processing chamber 150 having the pedestal assembly 190 in a cleaning position. The processing chamber 150 is configured to deposit a variety of materials (e.g., metals, polymers, or other deposition materials) onto a substrate disposed within the processing chamber 150. The processing chamber 150 includes the pedestal assembly 190, a lid assembly 100, a chamber body 120, a choke plate 195, a pumping plate 175, and a control unit 180. The chamber body 120 is configured to protect substrates disposed within the chamber body 120 from the environment outside the body. In general, the processing chamber 150 may be used to perform any type of substrate processing including, for example, chemical vapor deposition (CVD), plasma enhanced CVD (PE-CVD), plasma vapor deposition (PVD), atomic layer deposition (ALD), pulsed-CVD, plasma enhanced-ALD (PE-ALD), derivatives thereof, or combinations thereof. The processing chamber 150 can be used to further process (e.g., anneal) deposited materials. Thus, both the deposition processes and subsequent processing steps may be performed in-situ in the same processing chamber 150.

The deposition process includes providing power (e.g., RF power) to the processing chamber 150 to create an electrical bias between a showerhead 156 and the pedestal assembly 190. An RF return path 101 enables the power provided to the processing chamber to return to a ground.

As shown, the lid assembly 100 includes a showerhead 156 having holes 109. The lid assembly 100 is configured to deliver a processing gas through the holes 109 and into a processing region 126 disposed below the showerhead 156. The processing gas may be supplied from a processing gas source. The lid assembly 100 may include water channels to regulate the temperature of the lid assembly 100 during the deposition process.

The pedestal assembly 190 is configured to support a substrate (not shown) during processing, such as during the deposition of one or more layers on the substrate. As shown, the pedestal assembly 190 includes a heater pedestal 152, a pedestal stem 154, an isolator plate assembly 130, a ground ring 140, and a ground plate 160. The heater pedestal 152 may be configured to support the substrate. The heater pedestal 152 is connected to the pedestal stem 154 and may be vertically moved within the processing chamber 150. The heater portion of the heater pedestal 152 may include a ceramic material. A processing region 126 is defined between the heater pedestal 152 and the showerhead 156.

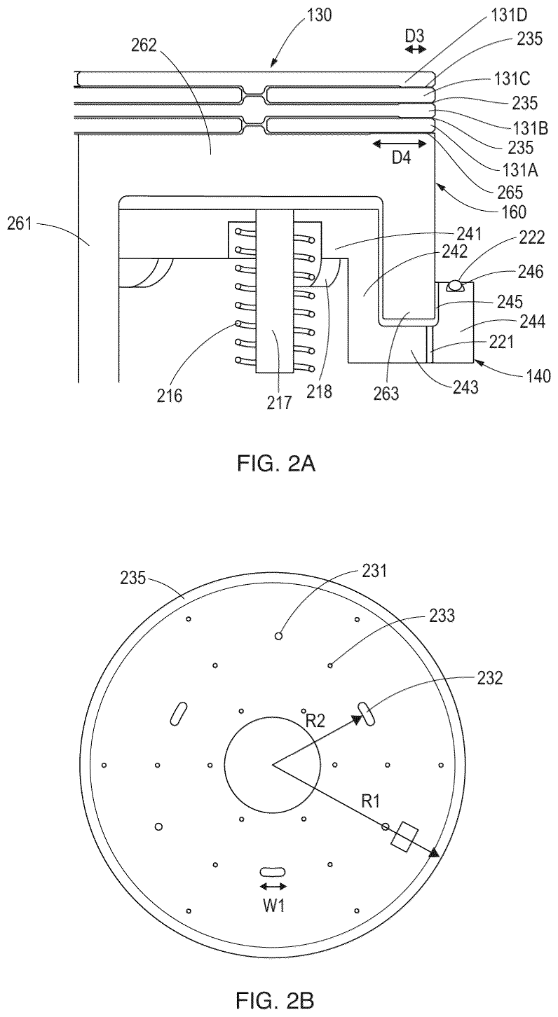

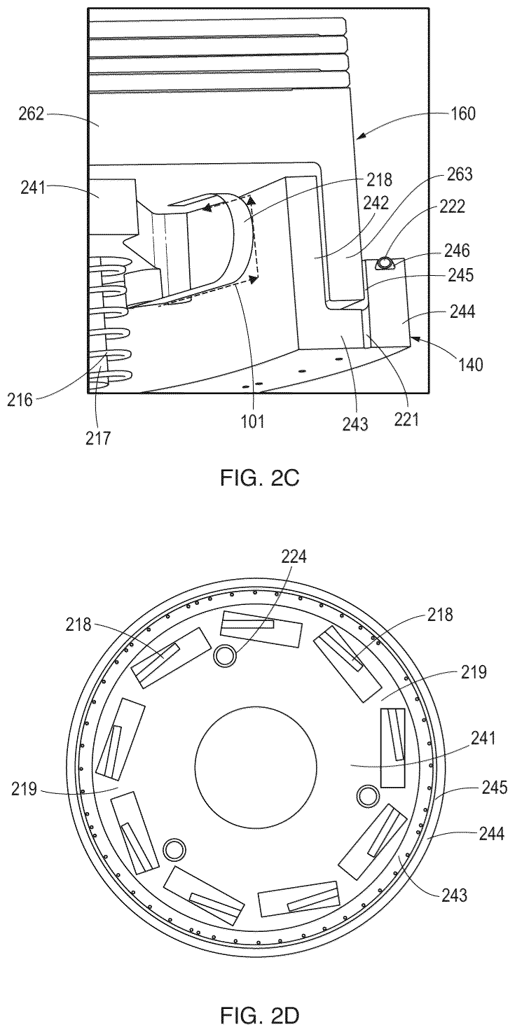

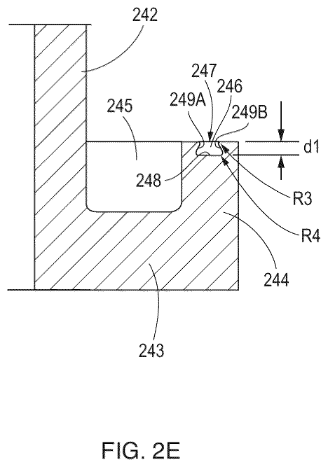

FIG. 2A is a cross-sectional view of the isolator plate assembly 130, the ground plate 160, and the ground ring 140. FIG. 2B is a top view of a plate of the isolator plate assembly 130. The heater pedestal 152 is disposed over the isolator plate assembly 130. The isolator plate assembly 130 may include three or more plates 131, such as a first plate 131A, a second plate 131B, a third plate 131C, and a fourth plate 131D. Each of the plates may include one or more lift pin holes 231, one or more alignment tabs 232, and a plurality of protrusions 233. The plurality of protrusions are configured to assist in aligning the plates and to control radial shifts of the plates 131.

The one or more lift pin holes 231 are configured to enable one or more lift pins (not shown) to lift the substrate off of the heater pedestal 152, such that the substrate can be removed from the processing chamber 150 and/or to enable the one or more lift pins to receive the substrate when the substrate is loaded into the processing chamber 150.

The isolator plate assembly 130 may have a thickness of about 20 mm to about 30 mm, such as about 24 mm. Each plate of the isolator plate assembly 130 may have a thickness of about 5 mm to about 7 mm. The individual plates 131, however, may vary in their thicknesses, e.g., the first plate 131A may have a thickness of about 5.5 mm to about 5.8 mm, the second plate 131B may have a thickness of about 5.55 mm to about 5.9 mm, the third plate 131C may have a thickness of about 5.5 mm to about 5.8 mm, and the fourth plate 131D may have a thickness of about 6.5 mm to about 6.8 mm. The plates may have a radius R1 of about 150 mm to about 200 mm, such as about 170 mm.

Each plate of the isolator plate assembly 130 may further include a radial step 235 at the outer edge of the plates 131. The radial step 235 may have a height of about 0.25 mm to about 0.5 mm, such as about 0.37 mm. The radial step 235 extends a distance D3 radially inward from the edge of the plate 131. The distance D3 is from about 5 mm to about 10 mm, such as about 10.5 mm. The radial step 235 may reduce the diffusion of cleaning gases and process gases between the plates 131, which may lead to a reduction in the corrosion of the isolator plate assembly 130.

The one or more alignment tabs 232 enable the alignment of the plates 131. The one or more alignment tabs 232 may be spaced apart from the center of the plate at a radius R2 of about 100 mm to about 120 mm. The one or more alignment tabs 232 may have a width W1 of about 20 mm to about 30 mm, such as about 25.4 mm.

The plurality of protrusions 233 may include about 6 to about 30 protrusions, such as about 18 protrusions. Each protrusion may have a diameter of about 1 mm to about 3 mm, such as about 2 mm, and a height of about 0.25 mm to about 1.0 mm, such as about 0.5 mm. Each plate of the isolator plate assembly 130 may include of a metal containing material, such as an aluminum containing material (e.g., alumina), nickel containing materials, titanium containing materials, molybdenum containing materials, tungsten containing materials, or combinations thereof.

Including multiple plates (e.g., three or more plates 131) in the isolator plate assembly 130 enables a reduction in the temperature of the isolator plate assembly 130. For example, at higher processing temperatures (e.g., 650° C.), the isolator plate assembly 130 may increase to a temperature of less than about 250° C., such as less than about 200° C. In addition, including multiple plates in the isolator plate assembly 130 enables a reduction in a temperature of the ground plate 160. The ground plate 160 may increase to a temperature of less than about 300° C., such as less than about 275° C. By increasing the number of plates and decreasing the thickness of each plate 131, the isolator plate assembly 130 is able to more efficiently disperse the heat from processing operations.

Generally, as the temperature of the ground plate 160 and the multiple plates of the isolator plate assembly 130 increases, the material of the ground plate 160 and the multiple plates of the isolator plate assembly 130 will expand. As the material expands, the stress within the material increases. Reducing the temperature of the isolator plate assembly 130 and the ground plate 160 may reduce the stress in the ground plate 160 and the multiple plates of the isolator plate assembly 130. The ground plate 160 may have a stress less of than about 100 MPa, such as less than about 50 MPa. The isolator plate assembly 130 may have a stress of less than about 75 MPa, such as less than about 60 MPa.

The isolator plate assembly 130 is disposed over the ground plate 160. The ground plate 160 includes a cylindrical core 261, an annular body 262, and an annular projection 263. The cylindrical core 261 annularly surrounds the pedestal stem 154. The annular projection 263 is spaced radially outward from the cylindrical core 261. The annular body 262 extends between the cylindrical core 261 toward the annular projection 263. The annular body has a thickness of about 20 mm to about 30 mm, such as about 24.5 mm.

A top surface of the ground plate 160 may include a radial step 265. The radial step 265 may have a height of about 0.25 mm to about 0.5 mm, such as about 0.37 mm. The radial step 265 extends a distance D4 radially inward from the edge of the plates 131. The distance D4 is about 15 mm to about 30 mm, such as about 22 mm. The radial step 265 may reduce the diffusion of cleaning gases and process gases between the isolator plate assembly 130 and the ground plate 160, which may lead to a reduction in the corrosion of the isolator plate assembly 130 and the ground plate 160.

The ground plate 160 may include a metal containing material, such as an aluminum containing material (e.g., alumina), nickel containing material, titanium containing material, molybdenum containing material, tungsten containing material, or combinations thereof. In some embodiments, the ground plate 160 may have a coating. The coating may include a metal containing material, such as an aluminum containing material (e.g., alumina), nickel containing material, titanium containing material, molybdenum containing material, tungsten containing material, or combinations thereof. The use of aluminum containing materials may reduce the corrosion of the ground plate 160 when exposed to cleaning gases (e.g., NF3) and processing gases. The reduction in corrosion may eliminate the need for protective components, such as an outer isolator, which would otherwise be required to isolate the ground plate 160 from the cleaning and processing gases. Eliminating the need for protective components may result in a decrease in manufacturing costs.

The components of the ground plate 160 (e.g., the cylindrical core 261), the annular body 262, and the annular projection 263 may be a single unitary piece. Implementing the ground plate 160 as a single unitary piece removes the need for mechanical couplers between the individual components of the ground plate 160, as well as any gaskets between the individual components of the ground plate 160. Reducing the number of mechanical couplers and/or gaskets may result in a decrease in manufacturing costs and may reduce the likelihood of corrosion and contamination from corrosion.

The ground plate 160 is disposed over and in spaced apart from the ground ring 140. The ground ring 140 includes an annular body 241, an annular wall 242, an annular connector 243, and an annular tab 244. The annular wall 242 and the annular tab 244 form an annular gap 245. The annular gap 245 is configured to receive the annular projection 263. The annular projection 263, however, does not contact the annular wall 242, the annular connector 243, or the annular tab 244. The annular connection includes one or more purge holes 221. The one or more purge holes 221 introduce purge gases from the chamber body 120 to the processing region 126.

FIG. 2C is a cross-sectional perspective view of the ground plate 160 and the ground ring 140. The ground ring 140 further includes a spring 216 and a shoulder screw 217. The spring 216 has a diameter of about 1.85 mm to about 2.3 mm. Each of the above listed components may include a nickel containing material, a chromium containing material, a molybdenum containing material, or a combination thereof, such as a nickel-chromium-molybdenum alloy (e.g., Hastelloy C276). The use of a nickel-chromium-molybdenum alloy may reduce the corrosion of the components, which may improve the longevity of the processing chamber 150 and decrease the likelihood of substrate contamination.

A RF strap 218 spans between the ground ring 140 and the ground plate 160. The processing chamber 150 may include one or more RF straps 218, such as about 6to 12 RF straps 218, such as about 9 RF straps 218. The RF strap 218 is configured to provide an electrical path as part of the RF return path 101 between the ground plate 160 and the ground ring 140.

The substrate may be supported on the heater pedestal 152 while the heater pedestal 152 is in a raised, deposition position. In the deposition position, the heater pedestal 152 holds the substrate in close opposition to the lower surface of the showerhead 156. The processing space of the processing region 126 is from about 25 mm to about 30 mm, such as about 28 mm. The processing space allows for a variation of different deposition processes (e.g., CVD, PVD, ALD) and deposition parameters.

In a lowered, cleaning position, the processing chamber 150 may be cleaned using cleaning gases (e.g., NF3). The cleaning space of the processing region is from about 75 mm to about 100 mm, such as about 90 mm.

In a further lowered, transfer position, the one or more lift pins can receive the substrate loaded into the processing chamber 150 through a loading port (not shown) in the chamber body 120.

The RF strap 218 is configured to bend and flex as the pedestal assembly 190 moves from the cleaning position to the processing position, and vice versa. In the processing position, the RF strap 218 may bend to a distance greater than about 50 mm, such as greater than about 55 mm, such as greater than about 60 mm. In the cleaning position, the RF strap 218 may bend to a distance of about 25 mm to about 35 mm, such as about 30 mm. The RF strap 218 has a thickness of about 1 mm. The RF strap 218 may include a nickel containing material, a chromium containing material, a molybdenum containing material, or a combination thereof, such as a nickel-chromium-molybdenum alloy (e.g., Haynes 242). The RF strap 218 may, in some embodiments, be coated. The coating may be a metal containing material, such as an aluminum containing material (e.g., alumina), nickel containing material, titanium containing material, molybdenum containing material, tungsten containing material, or combinations thereof. The use of a nickel-chromium-molybdenum alloy and an aluminum containing material coating may reduce the corrosion of the RF strap 218, which may improve the longevity of the processing chamber 150 and decrease the likelihood of substrate contamination.

FIG. 2D is a top view of the ground ring 140. The ground ring 140 further includes a plurality of bridge structures 219. The bridge structures 219 spans between the annular body 241 and the annular wall 242. The annular body 241 of the ground ring 140 further includes shoulder screw holes 224. The shoulder screw holes 224 are configured to allow the shoulder screw 217 to engage the ground plate 160.

In the processing position, the spring 216 has a preload height between 30 mm and 70 mm, such as 55 mm. The preload height enables the substrate release position to be further distanced from a bottom plate 199. Increasing the distance between the substrate release position and the bottom plate 199 may reduce spring interference with the bottom plate 199. In addition, the preload height may reduce the preload force on the ground ring. The preload force may be less than 25 kg·m/s², such as less than 20 kg·m/s².

FIG. 2E is a cross-sectional view of the annular tab 244. The annular tab 244 further includes a groove 246. The groove 246 includes an opening 247, a distal end 248, a first sidewall 249A and a second sidewall 249B. The depth d1 of the groove 246 is from about 2.5 mm to about 5 mm, such as about 3.25 mm to about 3.5 mm. The opening 247 has a radius R3 of about 4.5 mm to about 5.0 mm, such as about 4.7 mm. The first sidewall 249A and second sidewall 249B extend from the opening 247 to the distal end 248 of the groove 246. The distal end 248 has a radius R4 of about 4.75 mm to about 5.25 mm, such as about 4.84 mm.

The groove 246 of the annular tab 244 is configured to receive a RF gasket 222. The RF gasket 222 provides an electrical connection between the ground ring 140 and the choke plate 195. The RF gasket 222 may coiled wire. The diameter of the coil may be about 5 mm to about 6 mm, such as about 5.46 mm. The diameter of the RF gasket 222 may be about 350 mm to about 400 mm, such as about 385 mm. The RF gasket 222 may include a nickel containing material, a chromium containing material, a molybdenum containing material, or a combination thereof, such as a nickel-chromium-molybdenum alloy (e.g., Hastelloy C276). The use of a nickel-chromium-molybdenum alloy may reduce the corrosion of the components, which may improve the longevity of the processing chamber 150 and decrease the likelihood of substrate contamination.

The control unit 180 is configured to control the various components of the processing chamber 150. The control unit 180 can be one of any form of a general purpose computer processor that can be used in an industrial setting for controlling various chambers and sub-processors. As shown, the control unit 180 includes a central processing unit (CPU) 182, support circuitry 184, and memory 186. The CPU 182 can use any suitable memory 186, such as random access memory, read only memory, floppy disk drive, compact disc drive, hard disk, or any other form of digital storage, local or remote. Various support circuits may be coupled to the CPU 182 for supporting the processing chamber 150. The control unit 180 can be coupled to another controller that is located adjacent individual chamber components. Bidirectional communications between the control unit 180 and various other components of the processing chamber 150 are handled through numerous signal cables collectively referred to as signal buses. The control unit 180 can also be configured to provide a RF power to the processing chamber along the RF return path 101 to create an electrical bias between the showerhead 156 and the pedestal assembly 190. Further, the control unit 180 can be configured to move the pedestal assembly 190 between the cleaning position, the transfer position, and the processing position.

In the processing position, the annular tab 244 of the ground ring 140 is configured to engage the choke plate 195. The RF gasket 222 provides an electrical connection between the ground ring 140 and the choke plate 195. While in the processing position, the lid assembly 100, the pumping plate 175, the choke plate 195, the ground ring 140, and the ground plate 160 provide the RF return path 101 from the control unit 180 to ground.

The components of the processing chamber 150 may be coupled to one another using one or more mechanical couplers, e.g., rivets, strews, or other types of hardware. The mechanical couplers may include a metal containing material, such as an aluminum containing material (e.g., alumina), nickel containing material, titanium containing material, molybdenum containing material, tungsten containing material, or combinations thereof. The use of aluminum containing materials reduces the corrosion of the ground plate 160 when exposed to cleaning gases (e.g., NF3) and processing gases. Reducing the corrosion of the mechanical couplers may improve the longevity of the processing chamber 150 and decrease the likelihood of substrate contamination.

In summation, the present disclosure relates to a processing chamber. The process chamber includes a lid assembly, a choke plate, a pedestal assembly, a ground plate, and a ground ring. A processing region is defined between the lid assembly and the pedestal assembly. The pedestal assembly includes an isolator plate assembly. The isolator plate assembly includes three or more plates. Each plate includes one or more alignment tabs, one or more protrusions, one or more lift pin holes, a ground plate, and a ground ring. The lid assembly, choke plate, and pedestal assembly form a RF return path. The ground plate, includes a cylindrical core, an annular body, and an annular projection. The ground ring includes an annular body, an annular wall, an annular connector, and an annular tab. The ground ring and the ground plate are electrically connected via a RF strap. Various embodiments described herein allow for a reduction in the corrosion and/or other types of damage that may occur when processing a substrate within a processing chamber. Additionally, various embodiments enable the costs of components included in a processing chamber to be reduced, for example, by reducing manufacturing and material costs.

While the foregoing is directed to embodiments of the present disclosure, other and further embodiments of the disclosure may be devised without departing from the basic scope thereof.

What is claimed is:

1. A processing chamber, comprising:
a lid assembly;
a choke plate;
a pedestal assembly, wherein a processing region is defined between the lid assembly and the pedestal assembly, the pedestal assembly comprising:
an isolator plate assembly, comprising three or more plates, wherein each plate comprises:
one or more alignment tabs;
one or more protrusions;
one or more lift pin holes;
a ground plate; and
a ground ring,
wherein the lid assembly, the choke plate, and the pedestal assembly form a RF return path.

2. The processing chamber of claim 1, wherein the plates of the isolator plate assembly comprise an aluminum containing material.

3. The processing chamber of claim 1, wherein the plates of the isolator plate assembly further comprise a radial step having a height of about 0.25 mm to about 0.5 mm.

4. The processing chamber of claim 1, wherein the plates of the isolator plate assembly have a thickness of about 5 mm to about 7 mm.

5. The processing chamber of claim 1, wherein the isolator plate assembly has a thickness of about 20 mm to about 30 mm.

6. The processing chamber of claim 1, wherein the one or more protrusions have a diameter of about 1 mm to about 3 mm and a height of about 0.25 mm to about 1.0 mm.

7. The processing chamber of claim 1, wherein the alignment tabs are spaced apart from a center of the plate at a radius of about 100 mm to about 120 mm.

8. A processing system suitable for semiconductor substrate processing comprising:
a lid assembly;
a choke plate;
a pedestal assembly, wherein a processing region is defined between the lid assembly and the pedestal assembly, the pedestal assembly comprising:
an isolator plate assembly;
a ground plate, comprising;
a cylindrical core;
an annular body; and
an annular projection; and
a ground ring,
wherein the lid assembly, the choke plate, and the pedestal assembly form a RF return path.

9. The processing system of claim 8, wherein the processing region in a processing position is about 25 mm to about 30 mm.

10. The processing system of claim 8, wherein the processing region in a cleaning position from about 75 mm to about 100 mm.

11. The processing system of claim 8, wherein the ground plate is a unitary piece.

12. The processing system of claim 8, wherein the ground plate comprises an aluminum containing material.

13. The processing system of claim 8, wherein the ground plate further comprises a radial step having a height of about 0.25 mm to about 0.5 mm.

14. The processing system of claim 13, wherein the radial step extends radially inward from an edge of the ground plate about 15 mm to about 30 mm.

15. A control unit of a process system storing instructions that, when executed by a processor, cause the system to:
process a substrate within a processing chamber by applying a RF power to the processing chamber along a RF return path to create a bias between a showerhead and a pedestal assembly and processing the substrate, wherein the processing chamber comprises:
a lid assembly, comprising the showerhead having one or more holes;
a choke plate;
a pedestal assembly, wherein a processing region is defined between the lid assembly and the pedestal assembly, the pedestal assembly comprising:
an isolator plate assembly;
a ground plate; and
a ground ring, comprising:
an annular body, wherein the ground ring and the ground plate are electrically connected via a RF strap;
an annular wall;
an annular connector; and
an annular tab,
wherein the lid assembly, the choke plate, and the pedestal assembly form a RF return path.

16. The process system of claim 15, wherein the annular tab further comprises a groove, the groove configured to receive a RF gasket.

17. The process system of claim 16, wherein the RF gasket is configured to provide an electrical connection between the ground ring and the choke plate.

18. The process system of claim 16, wherein the RF gasket comprises a nickel containing material, a chromium containing material, a molybdenum containing material, or a combination thereof.

19. The process system of claim 16, wherein the RF gasket has a diameter of about 350 mm to about 400 mm.

20. The process system of claim 16, wherein the RF gasket comprises a coiled wire having a diameter of about 5 mm to about 6 mm.
